(19) United States
(12) Patent Application Publication
(10) Pub. No.: US 2024/0222160 A1
(43) Pub. Date: Jul. 4, 2024

(54) CEILING HEATER, SUBSTRATE PROCESSING METHOD, METHOD OF MANUFACTURING SEMICONDUCTOR DEVICE AND SUBSTRATE PROCESSING APPARATUS

(71) Applicant: Kokusai Electric Corporation, Tokyo (JP)

(72) Inventors: Shinobu SUGIURA, Toyama (JP); Tetsuya KOSUGI, Toyama (JP)

(21) Appl. No.: 18/608,198

(22) Filed: Mar. 18, 2024

Related U.S. Application Data
(63) Continuation of application No. PCT/JP2022/024429, filed on Jun. 17, 2022.

(30) Foreign Application Priority Data
Dec. 6, 2021 (JP) 2021-197882

(51) Int. Cl. H01L 21/67; H01L 21/02

(52) U.S. Cl. CPC H01L 21/67109; H01L 21/0217

(57) ABSTRACT

To suppress deformation of a heating element, there is provided a technique that includes: a disk-shaped base structure; and a heating element continuously extending to cover multiple regions of the base structure, wherein a circle centered on a center of the base structure is divided into fan shapes by the regions. A portion of the heating element in each of the plurality of regions is connected to another portion of the heating element in an adjacent region thereof at a predetermined location. The base structure includes a groove corresponding to a shape of the heating element, a wall is formed on an area of the base structure other than where the groove is located, and an interval between portions of the heating element located in two adjacent regions among the plurality of regions is set to be wider than a width of the wall separating the two adjacent regions.

### CROSS REFERENCE TO RELATED APPLICATIONS

This application is a bypass continuation application of PCT International Application No. PCT/JP2022/024429, filed on Jun. 17, 2022, in the WIPO, the international application being based upon and claiming the benefit of priority from Japanese Patent Application No. 2021-197882, filed on Dec. 6, 2021, in the Japanese Patent Office, the entire contents of which are hereby incorporated by reference.

### TECHNICAL FIELD

The present disclosure relates to a ceiling heater, a substrate processing method, a method of manufacturing a semiconductor device and a substrate processing apparatus.

### BACKGROUND

According to some related arts, as a part of a manufacturing process of a semiconductor device, a process of forming a film on a substrate placed in a process vessel may be performed while heating an inside of the process vessel with a heater.

### SUMMARY

According to the present disclosure, there is provided a technique capable of suppressing a deformation of a heating element.

According to an aspect of the present disclosure, there is provided a technique using a ceiling heater is provided above a reaction tube and includes: a base structure of a disk-shape; and a heating element continuously extending to cover a plurality of regions of the base structure, wherein a circle centered on a center of the base structure is divided into fan shapes by the plurality of regions, wherein a portion of the heating element located in each of the plurality of regions is connected to another portion of the heating element located in an adjacent region thereof at a predetermined location, and wherein the base structure is provided with a groove corresponding to a shape of the heating element, a wall is formed on an area of the base structure other than where the groove is located, and an interval between portions of the heating element located respectively in two adjacent regions among the plurality of regions is set to be wider than a width of the wall separating the two adjacent regions.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2 is a diagram schematically illustrating a configuration of a controller of the substrate processing apparatus according to the embodiments of the present disclosure.

FIG. 3 is a flow chart schematically illustrating a substrate processing according to the embodiments of the present disclosure.

FIG. 4 is a diagram schematically illustrating an installation state of a ceiling heater according to the embodiments of the present disclosure.

FIG. 5 is a diagram schematically illustrating an enlarged cross-section of a part of the ceiling heater shown in FIG. 4.

FIG. 6 is a diagram schematically illustrating a heating element of the ceiling heater according to the embodiments of the present disclosure, when viewed from above.

FIG. 7 is a diagram schematically illustrating a base structure of the ceiling heater, when viewed from above, according to the embodiments of the present disclosure.

FIG. 8 is a diagram schematically illustrating a lid structure of the ceiling heater, when viewed from above, according to the embodiments of the present disclosure.

FIG. 9 is a diagram schematically illustrating the ceiling heater, when viewed from above, according to the embodiments of the present disclosure.

FIG. 10 is a diagram schematically illustrating an enlarged view of the vicinity of a folded portion of the heating element disposed at an outermost periphery of the ceiling heater shown in FIG. 9.

FIG. 11 is a diagram schematically illustrating a modified example of the ceiling heater, when viewed from above, according to the embodiments of the present disclosure.

### DETAILED DESCRIPTION

### (1) Configuration of Substrate Processing Apparatus

Hereinafter, one or more embodiments (also simply referred to as “embodiments”) of the technique of the present disclosure will be described in detail with reference to the drawings. Like reference numerals represent like components in the drawings, and redundant descriptions related thereto will be omitted. Further, in the drawings, for the sake of clarity of the descriptions, features such as a width, a thickness and a shape of each component may be schematically illustrated as compared with actual structures. However, the drawings are merely examples of the embodiments, and the embodiments according to the technique of the present disclosure are not limited thereto.

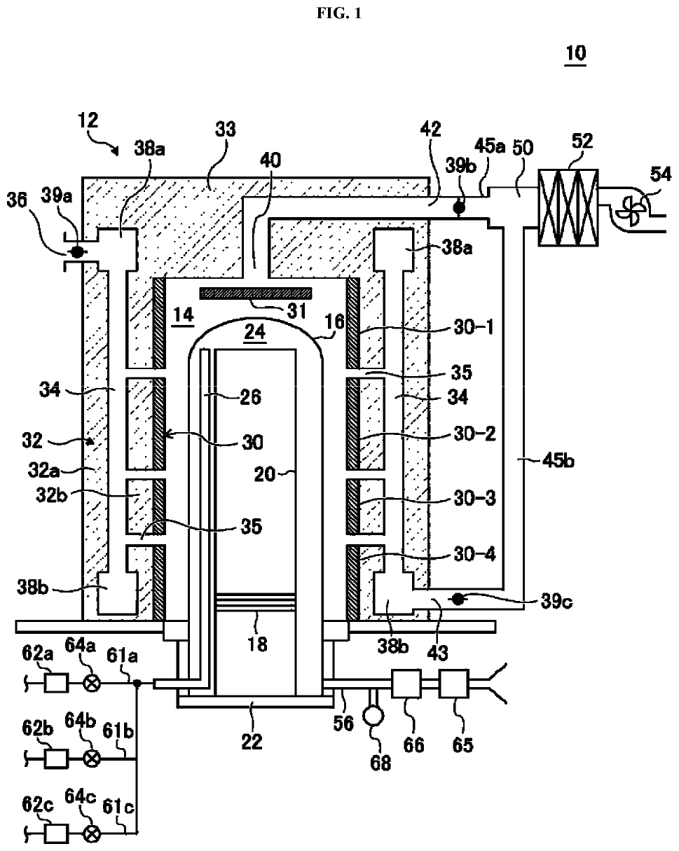

As shown in FIG. 1, a substrate processing apparatus 10 may include: a heater (which is a heating apparatus or a heating structure) 12 of a cylindrical shape; a reaction tube 16 of a cylindrical shape accommodated inside of the heater 12 and provided with a furnace space 14; and a boat 20 serving as a substrate retainer provided in the reaction tube 16 and capable of accommodating (supporting) a plurality of substrates including a substrate 18 to be processed in the reaction tube 16. Hereinafter, the plurality of substrates including the substrate 18 may also be simply referred to as “substrates 18”. The boat 20 is configured to support the substrates 18 in the reaction tube 16 with an interval (gap) therebetween while the substrates 18 supported by the boat 20 are vertically arranged in a horizontal orientation in a multistage manner. The boat 20 is placed on a boat elevator (not shown) through a cap 22, and configured to be capable of being elevated or lowered by the boat elevator. Therefore, the boat 20 with the substrates 18 maybe transferred (loaded) into the reaction tube 16 and transferred (unloaded) out of the reaction tube 16 by an operation of the boat elevator.

A process chamber 24 where the substrates 18 are accommodated is defined by the reaction tube 16. A gas introduction pipe 26 communicating with the reaction tube 16 is provided, and gas pipes 61a, 61b and 61c are connected to the gas introduction pipe 26. Mass flow controllers (MFCs) 62a, 62b and 62c serving as flow rate controllers (flow rate control structures) and valves 64a, 64b and 64c serving as opening/closing valves are sequentially installed in this order at the gas pipes 61a, 61b and 61c, respectively, from upstream sides to downstream sides of the gas pipes 61a, 61b and 61c in a gas flow direction. A gas exhaust pipe 56 communicating with the reaction tube 16 is provided to exhaust an inner atmosphere of the process chamber 24. A pressure sensor 68 and an APC valve 66 serving as a pressure regulator (which is a pressure adjusting structure) and a vacuum pump 65 serving as a vacuum apparatus are sequentially installed in this order at the gas exhaust pipe 56 from an upstream side to a downstream side of the gas exhaust pipe 56 in the gas flow direction.

The heater 12 is of a cylindrical shape, and further includes a side heater (which is a side heat generating structure) 30 and a ceiling heater (which is an upper heat generating structure) 31. The side heater 30 is provided at an inner side of a heat insulating structure in which a plurality of heat insulators are stacked, and is configured to heat the inner furnace space 14 from a side portion of the inner furnace space 14. The ceiling heater 31 is configured to heat the inner furnace space 14 from an upper portion of the inner furnace space 14. The ceiling heater 31 is provided below an upper wall portion 33 of the heat insulating structure and above the reaction tube 16. The side heater 30 is divided into a plurality of zones along a substrate stacking direction, for example, is divided into four zones 30-1, 30-2, 30-3 and 30-4 from a top of the side heater 30. The side heater 30 is configured to control a heating temperature individually in each of the divided zones 30-1, 30-2, 30-3 and 30-4. The ceiling heater 31 will be described later in detail.

The heat insulating structure includes a sidewall portion 32 and the upper wall portion 33. The sidewall portion 32 is of a cylindrical shape, and serves as a part of the heat insulating structure. The upper wall portion 33 is configured to cover an upper end of the side wall portion 32, and serves as a part of the heat insulating structure. The sidewall portion 32 is of a multilayer structure. That is, the sidewall portion 32 includes a sidewall outer layer 32a serving as an outer side layer of the multilayer structure of the sidewall portion 32 and a sidewall inner layer 32b serving as an inner side layer of the multilayer structure of the sidewall portion 32. A cooling gas passage 34 of a cylindrical space is provided between the sidewall outer layer 32a and the sidewall inner layer 32b. Further, the side heater 30 is provided on an inner side of the side wall inner layer 32b, and an inner portion of the side heater 30 serves as a heat generating region (heat generating area). While the present embodiments will be described by way of an example in which the sidewall portion 32 is of the multilayer structure in which the plurality of heat insulators are stacked, the structure of the sidewall portion 32 is not limited thereto.

A cooling gas supply port 36 is provided at an upper portion of the sidewall outer layer 32a. Further, a rapid-cooling gas discharge port (also referred to as a “quenching gas exhaust port”) 42 communicating with the inner furnace space 14 is provided in the upper wall portion 33. In addition, a cooling gas discharge port 43 is provided at a lower portion of the sidewall outer layer 32a. The rapid-cooling gas discharge port 42 and the cooling gas discharge port 43 are connected to exhaust pipes 45a and 45b, respectively, and are joined together at a duct 50. A radiator 52 and an exhaust fan 54 are connected to the duct 50 from an upstream side to a downstream side of the duct 50 in the gas flow direction. A cooling gas heated in the heater 12 is discharged to the outside of the substrate processing apparatus 10 through the duct 50, the radiator 52 and the exhaust fan 54 described above.

According to the present embodiments, a valve 39a serving as an opening/closing valve is provided in the vicinity of the cooling gas supply port 36 and a duct 38a. Further, a valve 39b serving as an opening/closing valve is provided in the vicinity of the rapid-cooling gas discharge port 42 and the duct 50. In addition, a valve 39c serving as an opening/closing valve is provided in the vicinity of the cooling gas discharge port 43 and a duct 38b. By providing the valve 39b in the vicinity of the duct 50 or the valve 39c in the vicinity of the duct 38b, it is possible to reduce an influence of a convection from the duct 50 or the duct 38b to the rapid-cooling gas discharge port 42 or the cooling gas discharge port 43 when the rapid-cooling gas discharge port 42 or the cooling gas discharge port 43 is not in use. It is also possible to improve a temperature uniformity on a surface of the substrate 18 in the vicinity of the duct 50 or the duct 38b.

A supply of the cooling gas is adjusted by opening or closing the valve 39a and turning on or off the exhaust fan 54. The cooling gas passage 34 is closed or opened by opening or closing the valve 39b or the valve 39c and turning on or off the exhaust fan 54. Thereby, the cooling gas may be discharged through the rapid-cooling gas discharge port 42 or the cooling gas discharge port 43.

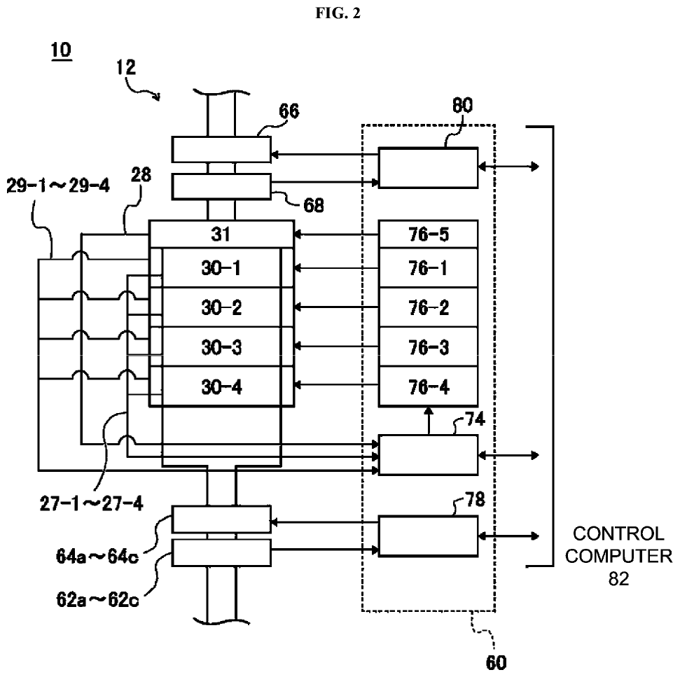

As shown in FIG. 2, first temperature sensors 27-1, 27-2, 27-3 and 27-4 serving as temperature detectors are installed at the plurality of zones 30-1, 30-2, 30-3 and 30-4 of the side heater 30, respectively. Further, a second temperature sensor 28 is installed at the ceiling heater 31. In addition, third temperature sensors 29-1, 29-2, 29-3 and 29-4 are installed in the process chamber 24. The third temperature sensors 29-1, 29-2, 29-3 and 29-4 maybe installed when acquiring a profile of the substrate processing apparatus 10 at the time of starting up the substrate processing apparatus 10, and may be removed from the process chamber 24 when performing a film forming process described later.

Hereinafter, a configuration of a controller 60 will be described. As shown in FIG. 2, the controller 60 is configured to control components of a semiconductor manufacturing apparatus serving as the substrate processing apparatus 10 such as the first temperature sensors 27-1, 27-2, 27-3 and 27-4, the second temperature sensor 28, the third temperature sensors 29-1, 29-2, 29-3 and 29-4, the MFCs 62a, 62b and 62c, the valves 64a, 64b and 64c, the APC valve 66 and the pressure sensor 68 based on values such as temperatures, pressures and flow rates set by a control computer 82 described later.

A temperature controller (which is a temperature control structure) 74 is configured to control heater drivers (which are heater driving structures) 76-1, 76-2, 76-3 and 76-4. Specifically, the temperature controller 74 controls the electric power supplied by the heater drivers 76-1, 76-2, 76-3 and 76-4 to the zones 30-1, 30-2, 30-3 and 30-4 of the side heater 30, respectively, such that that temperatures measured by the first temperature sensors 27-1, 27-2, 27-3 and 27-4 reach the temperatures set by the control computer 82. In addition, the temperature controller 74 controls the electric power supplied by the heater driver 76-1 and a heater driver 76-5 to the zone 30-1 and the ceiling heater 31, respectively, such that the temperatures measured by the first temperature sensor 27-1 and the second temperature sensor 28 reach the temperatures set by the control computer 82, specifically, such that the temperature of an upper substrate (for example, an uppermost substrate) among the substrates 18 reaches a desired temperature.

A flow rate controller (which is a flow rate control structure) 78 is configured to control the MFCs 62a, 62b and 62c and the valves 64a, 64b and 64c so as to control a flow rate of a gas introduced into the process chamber 24 of the reaction tube 16. That is, the flow rate controller 78 controls the MFCs 62a, 62b and 62c and the valves 64a, 64b and 64c such that the flow rate of the gas measured by a flow rate sensor reaches the flow rate of the gas set by the control computer 82. A pressure controller (which is a pressure control structure) 80 is configured to control components such as the APC valve 66 so as to control a pressure of the process chamber 24. That is, the pressure controller 80 controls the APC valve 66 such that an inner pressure of the reaction tube 16 measured by the pressure sensor 68 reaches the pressure set by the control computer 82.

### (2) Substrate Processing

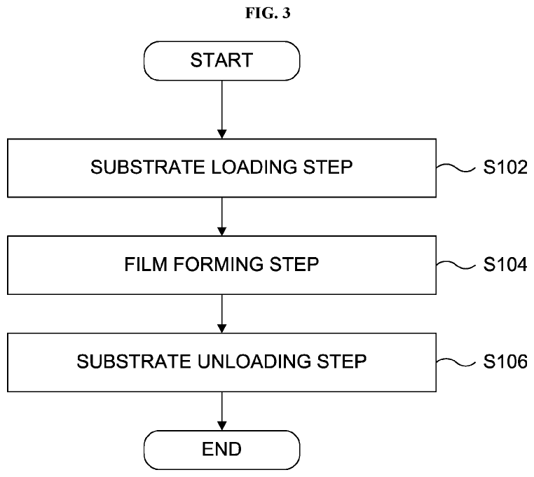

Subsequently, an outline of a substrate processing performed by using the semiconductor manufacturing apparatus serving as the substrate processing apparatus 10 will be described with reference to FIG. 3. The substrate processing is performed as a part of a manufacturing process of a semiconductor device (that is, a method of manufacturing the semiconductor device). Further, the substrate processing is performed as a substrate processing method of processing the substrate 18. For example, the substrate processing serves as a step in manufacturing the semiconductor device. In the following description, operations or processes performed by components constituting the substrate processing apparatus 10 are controlled by the controller 60.

In the present embodiments, an example of forming a film on the substrate 18 by alternately supplying a first process gas (source gas) and a second process gas (reactive gas) to the substrate 18 will be described. Hereinafter, an example in which a silicon nitride film (SiN film) serving as the film is formed on the substrate 18 by using a silicon source gas (which is a silicon-containing source gas in a liquid state at a room temperature) as the source gas and ammonia (NH₃) gas (which is a nitrogen-containing source gas) as the reactive gas will be described. For example, a predetermined film may be formed on the substrate 18 in advance. Further, a predetermined pattern may be formed on the substrate 18 or on the predetermined film in advance.

### <Substrate Loading Step S102>

In a substrate loading step S102, first, the substrates 18 are transferred (loaded) into the boat 20, and the boat 20 charged with the substrates 18 is then loaded into the process chamber 24.

### <Film Forming Step S104>

Subsequently, a film forming step S104 of forming the film on the surface of the substrate 18 is performed. In the film forming step S104, four steps described below (that is, a first step, a second step, a third step and a fourth step) are sequentially performed. Further, while performing the first through the fourth steps, the substrate 18 is heated to a predetermined temperature by the side heater 30. More specifically, an upper portion of the reaction tube 16 is heated to a predetermined set temperature by the ceiling heater 31 described in detail later. The predetermined set temperature is appropriately set depending on the source gas.

### <First Step>

In the first step, the silicon source gas is supplied into the process chamber 24. Specifically, the silicon source gas is supplied as follows. First, both of the valve 64a provided on the gas pipe 61a and the APC valve 66 provided on the gas exhaust pipe 56 are opened. Then, the silicon source gas whose flow rate is adjusted by the MFC 62a is introduced (passed) through the gas introduction pipe 26, and is supplied into the process chamber 24 through gas supply holes provided in the gas introduction pipe 26 while being exhausted through the gas exhaust pipe 56. In the present step, an inner pressure of the process chamber 24 (that is, the pressure of the process chamber 24) is maintained at a predetermined pressure. A film containing silicon (Si) is formed on the surface of the substrate 18 by supplying the silicon source gas.

### <Second Step>

In the second step, the valve 64a is closed to stop a supply of the silicon source gas into the process chamber 24. With the APC valve 66 of the gas exhaust pipe 56 open, the vacuum pump 65 exhausts the process chamber 24 to remove a residual gas from the process chamber 24. Further, the valve 64c provided in the gas pipe 61c is opened to supply an inert gas such as N2 whose flow rate is adjusted by the MFC 62c into the process chamber 24. Thereby, the residual gas in the process chamber 24 is purged.

### <Third Step>

In the third step, the NH₃ gas is supplied to the process chamber 24. Both of the valve 64b provided on the gas pipe 61b and the APC valve 66 provided on the gas exhaust pipe 56 are opened. Then, the NH₃ gas whose flow rate is adjusted by the MFC 62b is introduced (passed) through the gas introduction pipe 26, and is supplied into the process chamber 24 through the gas supply holes provided in the gas introduction pipe 26 while being exhausted through the gas exhaust pipe 56. In the present step, the inner pressure of the process chamber 24 is adjusted to a predetermined pressure. By supplying the NH₃ gas, the silicon source gas reacts with the NH₃ gas and the film containing silicon formed on the surface of the substrate 18. Thereby, the SiN film is formed on the substrate 18.

### <Fourth Step>

In the fourth step, an inside of the process chamber 24 is purged again with the inert gas. The valve 64b is closed to stop a supply of the NH₃ gas into the process chamber 24. With the APC valve 66 of the gas exhaust pipe 56 open, the vacuum pump 65 exhausts the process chamber 24 to remove a residual gas from the process chamber 24. Further, the valve 64c provided in the gas pipe 61c is opened to supply the inert gas such as the N₂ whose flow rate is adjusted by the MFC 62c into the process chamber 24. Thereby, the residual gas in the process chamber 24 is purged.

The SiN film of a predetermined thickness is formed on the substrate 18 by repeatedly performing a cycle including the first step to the fourth step a plurality number of times.

### <Substrate Unloading Step S106>

In a substrate unloading step S106, the boat 20 accommodating the substrate 18 with the SiN film formed thereon is unloaded out of the process chamber 24.

According to the present embodiments, a process gas (that is, the first process gas and the second process gas) is supplied into the process chamber 24 in a heated state by at least the side heater 30 and the ceiling heater 31. That is, while the cycle including the first step to the fourth step is repeatedly performed the plurality number of times, at least the ceiling heater 31 continues to heat the upper portion of the reaction tube 16 to maintain the predetermined set temperature.

### (3) Configuration of Ceiling Heater

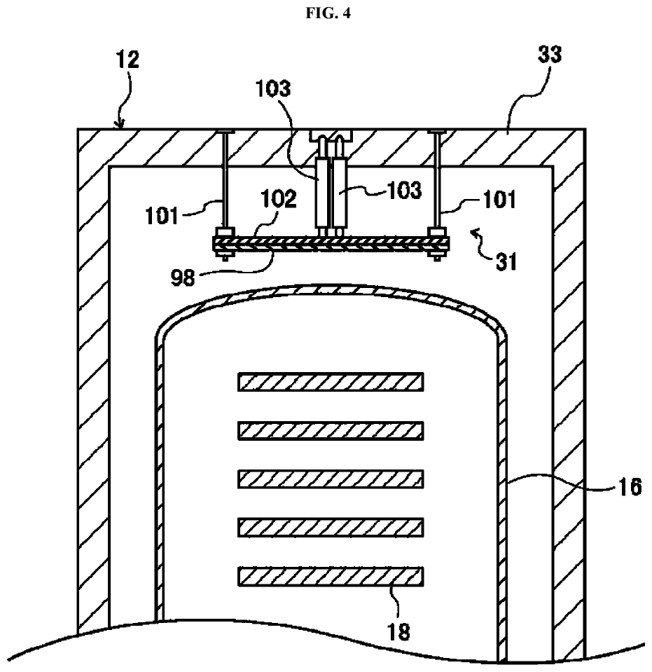

Subsequently, the ceiling heater 31 will be described in detail with reference to FIGS. 4 to 10. The present embodiments will be described by using the ceiling heater 31 provided above the reaction tube 16.

As shown in FIG. 4, the ceiling heater 31 is provided substantially horizontally above the reaction tube 16. The ceiling heater 31 is fixed in a suspended state by a support structure 101 provided on the upper wall portion 33 of the heater 12. A power feeder (which is a power supply) 103 provided on the upper wall portion 33 of the heater 12 is connected to a substantially central portion of the ceiling heater 31. An outer diameter of the ceiling heater 31 is set to be equal to or greater than an outer diameter of the substrate 18.

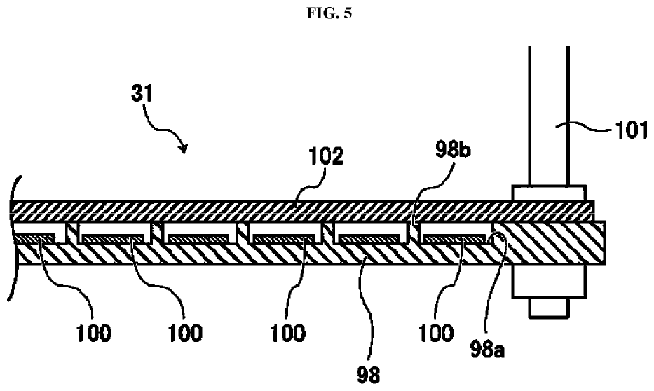

As shown in FIG. 5, the ceiling heater 31 may include: a base structure 98 which is electrically insulated and of a disk-shape; a heating element 100 which is an electric heating wire; and a lid structure 102 which is electrically insulated. The heating element 100 is accommodated in a groove 98a formed (provided) in the base structure 98. The base structure 98 is provided below the heating element 100, and is not provided with an opening. Thereby, the base structure 98 can substantially support an entirety of a bottom surface of the heating element 100, and can keep the heating element 100 flat. With such a configuration, while allowing the heating element 100 to move within the groove 98a due to a thermal expansion, even when the heating element 100 is plastically deformed, it is possible to prevent the heating element 100 from hanging down and coming into contact with the reaction tube 16.

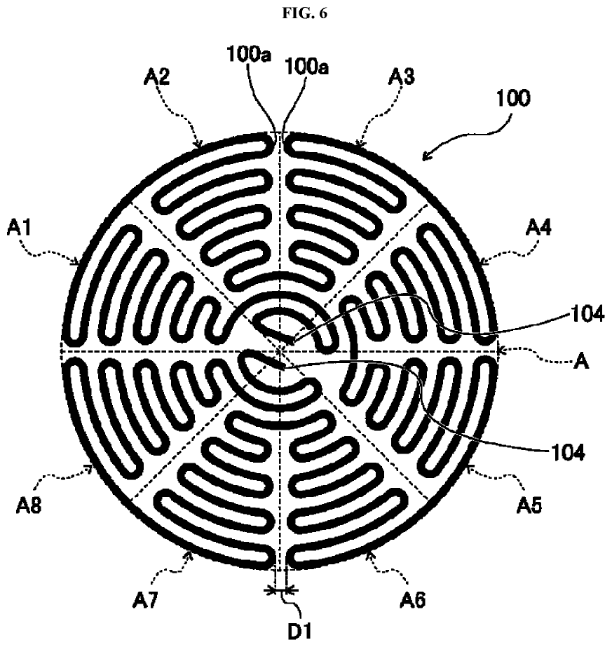

As shown in FIG. 6, the heating element 100 is configured to meander outward from a center portion toward an outer periphery thereof and inward from the outer periphery toward the center portion thereof within a plurality of regions (or areas) divided into fan shapes, and arc portions of the heating element 100 are formed in a concentric circle shape. End portions 104 of the heating element 100 located at the center portion of the ceiling heater 31 serve as power feeding ends to which power feed lines are connected, and each of the power feeding ends is connected to the power feeder 103.

The heating element 100 continuously extends to cover the plurality of regions of the base structure 98 wherein the plurality of regions are obtained by dividing a virtual circle centered on a center of the base structure 98 into the fan shapes. Specifically, the heating element 100 continuously curved in a meandering manner on the base structure 98 within regions A1, A2, A3, A4, A5, A6, A7 and A8, which are obtained by dividing a circle “A” (which is the virtual circle centered on the center of the base structure 98) into eight fan shapes. That is, the regions A1 to A8 are formed by equally dividing the circle A into eight fan shapes. The heating element 100 extends in a circumferential direction within each of the regions A1 to A8, and is formed in a meandering manner by or being folded back at a circumferential end of each region. Meandering patterns in the regions A1 and A2, regions A3 and A4, regions A5 and A6 and regions A7 and A8 are substantially the same except for the end portions 104, and form 4-fold rotational symmetry around a center of the circle A which is the virtual circle. That is, the heating element 100 is rotationally symmetric.

Specifically, the heating element 100 extends along a semicircle from one of the end portions 104 as a starting point, then changes its extension direction to extend outward in a radial direction, then changes its extension direction and to extend along another semicircle whose diameter is greater than its preceding semicircle, and then changes its extension direction to extend outward in the radial direction at the circumferential end of the region A1. Then, the heating element 100 changes its extension direction to extend along an arc portion (in the region A1) whose center angle is within 45° and whose diameter is greater than that of its preceding semicircle, then changes its extension direction to extend outward in the radial direction at another circumferential end of the region A1, then changes its extension direction to extend along another arc portion (in the region A1) whose center angle is within 45° and whose diameter is greater than that of its preceding arc portion (in the region A1), and then changes its extension direction to extend outward in the radial direction at the circumferential end of the region A1. As the heating element 100 repeatedly changes its extension direction and extends in the region A1 in a manner described above, the heating element 100 forms multiple portions arranged concentrically in the region A1 while meandering outward in the radial direction.

Then, when the heating element 100 changes its extension direction to extend so as to approach (or reach) an outermost arc portion on a peripheral portion of the circle A in the regions A1 and A2, the heating element 100 extends along the outermost arc portion whose center angle is greater than 45° and equal to or less than 90° and whose diameter is greater than that of its preceding arc portion (in the region A1). Then, the heating element 100 changes its extension direction to extend inward in the radial direction at the circumferential end of the region A2 opposite to the region A1. Then, the heating element 100 changes its extension direction to extend along an arc portion (in the region A2) whose center angle is within 45° and whose diameter is less than that of the outermost arc portion, and then changes its extension direction to extend inward in the radial direction at another circumferential end of the region A2. As the heating element 100 repeatedly changes its extension direction to extend in the region A2 in a manner described above, the heating element 100 forms multiple portions arranged concentrically in the region A2 while meandering inward in the radial direction.

Then, after the heating element 100 changes its extension direction to extend so as to approach (or reach) an arc portion (in the regions A2 and A3) on a central portion of the circle A, the heating element 100 changes its extension direction to extend along the arc portion (in the regions A2 and A3) whose center angle is greater than 45° and equal to or less than 90° and whose diameter is less than that of its preceding arc portion (in the region A2). Then, the heating element 100 changes its extension direction to extend outward in the radial direction at the circumferential end of the region A3 opposite to the region A2. Then, the heating element 100 changes its extension direction to extends along its preceding arc portion (in the region A3) whose center angle is within 45° and whose diameter is greater than that of the arc portion (in the regions A2 and A3), and then changes its extension direction to extend outward in the radial direction at another circumferential end of the region A3. As the heating element 100 repeatedly changes its extension direction and extends in the region A3 in a manner described above, the heating element 100 forms multiple portions arranged concentrically in the region A3 while meandering outward in the radial direction.

Then, after the heating element 100 changes its extension direction to extend so as to approach (or reach) an outermost arc portion on the peripheral portion of the circle A in the regions A3 and A4, similar to the heating element 100 in the region A2, the heating element 100 repeatedly changes its extension direction to extend between circumferential ends of the region A4. As the heating element 100 repeatedly changes its extension direction to extend in the region A4 in a manner described above, the heating element 100 forms multiple portions arranged concentrically in the region A4 while meandering inward in the radial direction.

Then, after the heating element 100 changes its extension direction to extend so as to approach (or reach) an arc portion on the central portion of the circle A in the regions A4 and A5, similar to the heating element 100 in the region A3, the heating element 100 repeatedly changes its extension direction to extend between circumferential ends of the region A5. As the heating element 100 repeatedly changes its extension direction to extend in the region A5 in a manner described above, the heating element 100 forms multiple portions arranged concentrically in the region A5 while meandering outward in the radial direction.

Then, after the heating element 100 changes its extension direction to extend so as to approach (or reach) an outermost arc portion on the peripheral portion of the circle A in the regions A5 and A6, similar to the heating element 100 in the region A2, the heating element 100 repeatedly changes its extension direction to extend between circumferential ends of the region A6. As the heating element 100 repeatedly changes its extension direction to extend in the region A6 in a manner described above, the heating element 100 forms multiple portions arranged concentrically in the region A6 while meandering inward in the radial direction.

Then, after the heating element 100 changes its extension direction to extend so as to approach (or reach) an arc portion on the central portion of the circle A in the regions A6 and A7, similar to the heating element 100 in the region A3, the heating element 100 repeatedly changes its extension direction to extend between circumferential ends of the region A7. As the heating element 100 repeatedly changes its extension direction to extend in the region A7 in a manner described above, the heating element 100 forms multiple portions arranged concentrically in the region A7 while meandering outward in the radial direction.

Then, after the heating element 100 changes its extension direction to extend so as to approach (or reach) an outermost arc portion on the peripheral portion of the circle A in the regions A7 and A8, similar to the heating element 100 in the region A2, the heating element 100 repeatedly changes its extension direction to extend between circumferential ends of the region A8. As the heating element 100 repeatedly changes its extension direction to extend in the region A8 in a manner described above, the heating element 100 forms multiple portions arranged concentrically in the region A8 while meandering inward in the radial direction. Then, after the heating element 100 changes its extension direction to extend so as to approach (or reach) an arc portion (in the region A8) on the central portion of the circle A, the heating element 100 changes its extension direction to extend along a semicircle (which is concentric to an outer circle) to the circumferential end of the region A6 adjacent to the region A5, then changes its extension direction to extend inward in the radial direction, then changes its extension direction to extend along another semicircle (which is concentric to the outer circle, and whose circumference is smaller than the outer circle) to the circumferential end of the region A8 adjacent to the region A1 toward the other one of the end portions 104 as an ending point.

In a manner described above, the heating element 100 is provided such that the two end portions 104 are connected in one stroke. The heating element 100 may be generally provided with a constant cross-sectional area such that a current density thereof is uniform. When the heating element 100 is made of a plate-shaped material, the heating element 100 may be provided with a substantially constant width. However, in order to improve a uniformity of the current density or a uniformity of a temperature elevation, or in order to extend a lifetime, for example, a cross-sectional area of each folded portion 100a of the heating element 100 may be increased or decreased. According to the present embodiments, the heating element 100 is configured to include a plurality of folded portions 100a, which are folded locations provided on the same circumference. Further, folded positions of the respective folded portions 100a of the heating element 100 in each region are configured to coincide in the radial direction and to be adjacent to each other in the circumferential direction.

Further, a maximum central angle of a continuous arc portions formed by the heating element 100 is 90° or less. Further, a portion of the heating element 100 located in each of the regions A1 to A8 is configured to be connected to another portion of the heating element 100 in its adjacent region at a predetermined location on the peripheral portion or the central portion of the circle A. In addition, the heating element 100 is separated from the heating element 100 in an adjacent region by a predetermined interval.

In a manner described above, the heating element 100 extends in the circumferential direction within each of the regions A1 to A8 of the fan shapes, and is configured such that the arc portions of the heating element 100 are formed in a concentric circle shape while meandering repeatedly by changing its extension direction to extending outward or inward in the radial direction at the circumferential ends of each of the regions A1 to A8. By configuring the heating element 100 to change its extension direction within the plurality of regions of the fan shapes, an amount or a direction of displacement due to the thermal expansion of the heating element 100 becomes similar between the inside and outside of each of the folded portions 100a. Thereby, it is possible to suppress a deformation of the heating element 100.

In the heating element 100 provided with such patterns described above, an elongation due to the thermal expansion or a plastic deformation is the largest at the outermost arc portions where each region is connected on the circumference of the circle A and whose length is approximately twice a length of the arc portion in each region of the circle A. It is preferable that an allowable expansion amount of each of the outermost arc portions is approximately twice or more than an allowable expansion amount of each arc portion disposed on the circumference of the circle A within each region. Further, an allowable expansion amount of an arc portion of the heating element 100 is set to be smaller than or equal to an allowable expansion amount of another arc portion of the heating element 100 immediately outside the above-mentioned arc portion. The heating element 100 set in a manner described above can move within the groove 98a by expansion. In particular, as the outermost arc portion expands, two portions of the heating element 100 in two adjacent regions connected by the outermost arc portion may move away from each other. However, such a movement converges within the two regions and will not spread to other regions. In other words, the expansion of each outermost arc portion affects locally, and since the outermost arc portions are symmetrical one another with respect to the center of the circle A, it is possible to suppress the displacement or the deformation of the entire heating element 100.

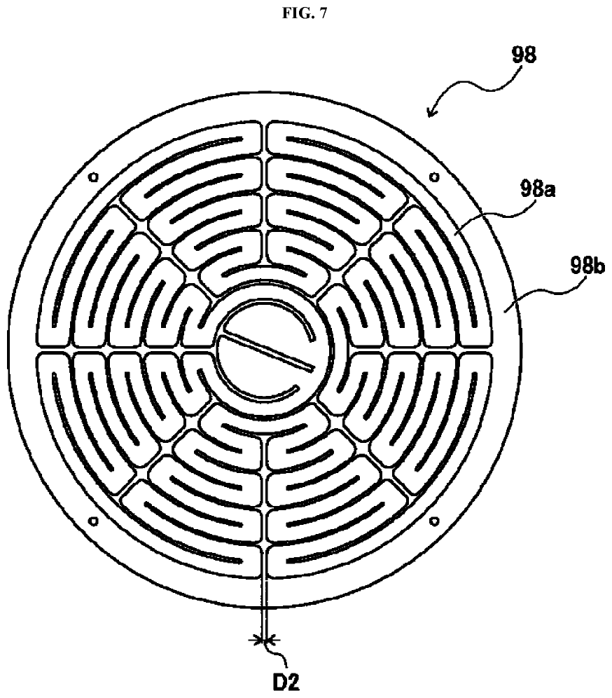

As shown in FIG. 7, the base structure 98 is provided with the groove 98a corresponding to the shape of the heating element 100, and a wall 98b is formed on an area other than where the groove 98a is located. Further, a back surface (lower surface) of a surface on which the groove 98a of the base structure 98 is provided and on which the reaction tube 16 is installed may be formed into a flat plate shape. For example, an inner portion of the base structure 98 is made of a transparent material or an opaque material such as synthetic quartz or alumina, and an inner surface of the groove 98a is roughened.

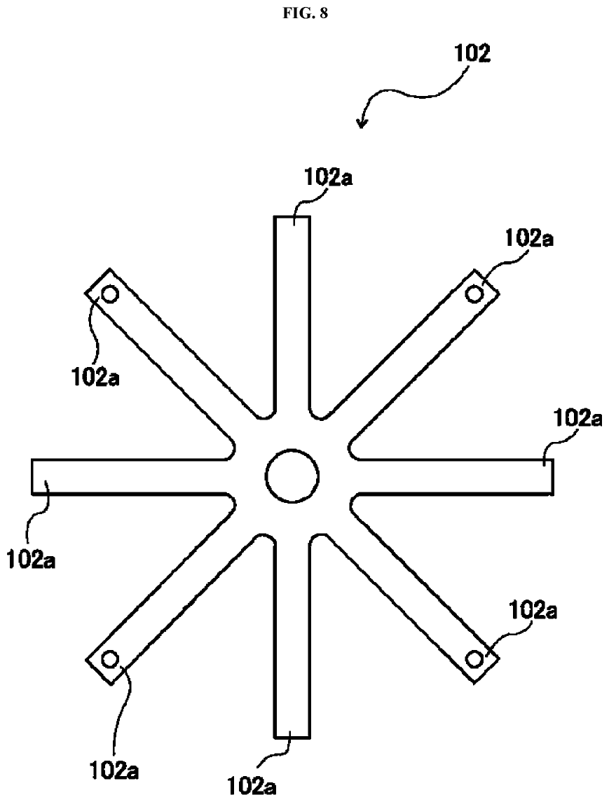

As shown in FIG. 8, the lid structure 102 is provided with eight arm structures 102a extending radially from a center of the lid structure 102. For example, the lid structure 102 is made of a material such as synthetic quartz.

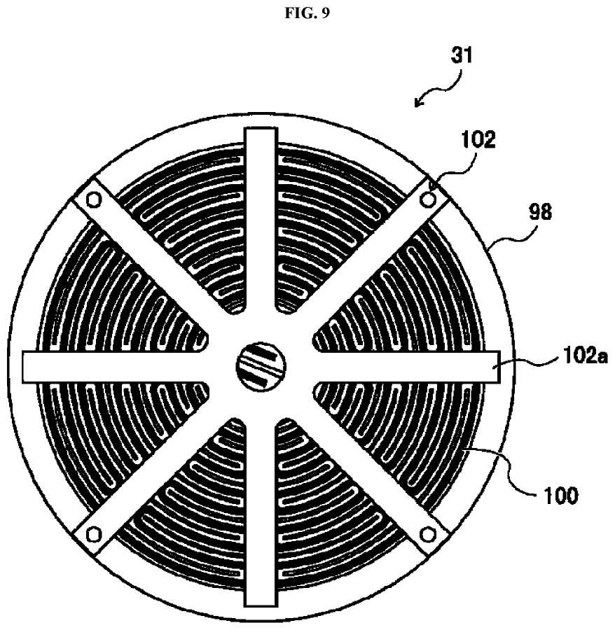

For example, as shown in FIG. 9, the heating element 100 is accommodated in and provided in the groove 98a of the base structure 98, and the lid structure 102 is attached thereon. That is, the heating element 100 is simply placed at a bottom of the groove 98a. Then, the base structure 98 and the lid structure 102 are fixed with screws on an outer peripheral side of the heating element 100. When fixing the base structure 98 and the lid structure 102, each of the arm structures 102a is arranged between two portions of the heating element 100 in two adjacent regions and along a boundary between the folded portions 100a between the adjacent regions. That is, the folded portions 100a of the adjacent regions are held between the base structure 98 and the lid structure 102 (arm structures 102a). That is, the base structure 98 or the heating element 100 is open upward at least partially. Thereby, the lid structure 102 capable of preventing the folded portions 100a from protruding from the groove 98a and contacting the heating element 100 in the adjacent region can be configured to be lightweight.

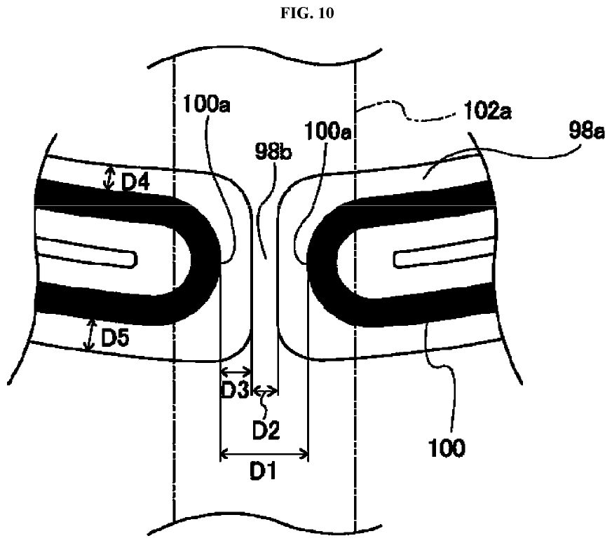

According to the present embodiments, as shown in FIG. 10, an interval D1 between the folded portions 100a of the adjacent regions is set to be wider than a width D2 of the wall 98b separating the two adjacent regions. That is, it is set such that the interval D1 is greater than the width D2. Further, a distance D3 between the wall 98b separating each region and the folded portion 100a of the heating element 100 closest to the circumference is set to be longer than an expansion amount due to the plastic deformation of the portion of the heating element 100 closest to the circumference. Such an expansion amount can be obtained empirically, assuming that it may occur during a normal use over an expected service life. In addition, a distance between a side portion of the heating element 100 provided to be extended in the circumferential direction in each region and the wall 98b is set such that, in a non-heating state, a distance D5 between the side portion of the heating element 100 provided on the peripheral portion of the circle A and the wall 98b is longer than a distance D4 between the side portion of the heating element 100 provided on the central portion of the circle A and the wall 98b. That is, it is set such that the distance D5 is greater than the distance D4. Thereby, even when the heating element 100 expands due to a repetition of the temperature elevation and a temperature lowering, it is possible to secure a space so as to prevent the heating element 100 from contacting (or hitting) the wall 98b constituting the base structure 98.

In the present embodiments, when the substrate 18 provided at an upper portion of the boat 20 (that is, the upper substrate) is heated by the side heater 30 alone (that is, the ceiling heater 31 is turned off), a peripheral portion of the substrate 18 is actively heated. Further, due to an influence of a heat escape from a central portion of the substrate 18, in particular, the heating at a central portion of the substrate 18 is insufficient. As a result, a temperature distribution on the surface of the substrate 18 may vary, and the temperature uniformity on the surface of the substrate 18 may deteriorate. That is, when the substrate 18 is heated by the side heater 30 alone, the temperature distribution on the surface of the substrate 18 may become a concave distribution in which a temperature at the central portion of substrate 18 is low.

Further, an iron-based alloy may be used as the material of the heating element 100, but such a heating element 100 undergoes the plastic deformation (elongation) due to the repetition of the temperature elevation and the temperature lowering. Such a plastic deformation is thought to be due to a fact that at least a part of a cross section of the heating element 100 is annealed while being subjected to a tensile stress during a cooling process, and an elongation amount accumulates depending on the number of times the temperature is elevated or lowered. Further, when the number of the repetition of the temperature elevation and the temperature lowering is small, it may not expand or may conversely contract. Since the elongation may occur even without an external force, it is difficult to suppress it completely. Thus, when the heating element 100 stretched to a limit that can be accommodated in the base structure 98 expands thermally while being partially restrained on the base structure 98, a buckling may occur in which an unrestrained portion of the heating element 100 pops out from the base structure 98. Such a buckling also serves as the plastic deformation, and may worsen as the elongation progresses. In other words, it has been a challenge to improve a durability of the ceiling heater 31.

According to the embodiments of the present disclosure, the heating element 100 changes its extension direction to extend and at the circumferential end of each of the plurality of regions divided into the fan shapes and a length of the arc portion on the same circumference is shortened. As a result, the expansion amount per each arc portion can be set to be small. Thereby, it is possible to suppress the deformation of the heating element 100, and it is possible to prevent the heating element 100 from protruding from the groove 98a formed (provided) in the base structure 98.

Further, by providing the ceiling heater 31 above the reaction tube 16, it is possible to stabilize the temperature above the reaction tube 16, and it is also possible to improve a thickness uniformity of a film to be formed.

That is, it is possible to prevent an undesirable deformation such as a lifting due to the plastic deformation of the heating element 100, and it is also possible to suppress a contact with the heating element 100 and a short circuit or a disconnection of the heating element 100. Further, it is possible to extend the lifetime of the ceiling heater 31.

### (4) Modified Example

The ceiling heater 31 in the embodiment described above may be modified as shown in the following modified example. Unless otherwise described, a configuration in the modified example is substantially the same as that in the embodiments described above, and the description thereof will be omitted.

### Modified Example

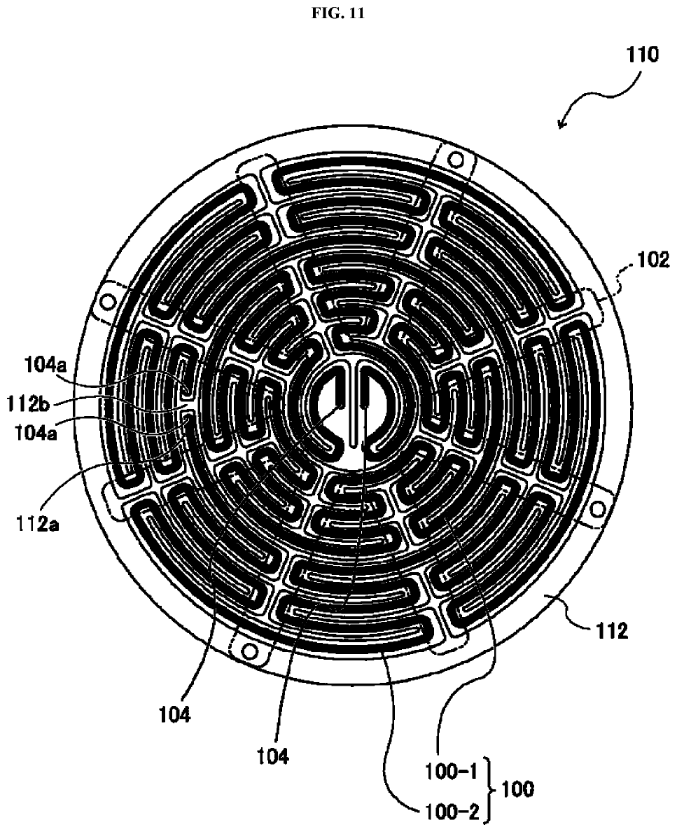

The modified example of the ceiling heater 31 described above will be described with reference to FIG. 11. A ceiling heater 110 in the modified example differs from the ceiling heater 31 described above in the shape of the heating element 100 and a base structure 112 accommodating the heating element 100. In FIG. 11, a lid structure 102 is shown with a broken line to make it easier to understand the shapes of the heating element 100 and the base structure 112 according to the present modified example.

The heating element 100 is configured to be divided into two parts in the ceiling heater 110. That is, as the heating element 100, two heating elements including a first heating element 100-1 and a second heating element 100-2 are used. The base structure 112 is provided with a groove 112a corresponding to the shape of the first heating element 100-1 and the second heating element 100-2, and a wall 112b is defined by locations (portions) other than a location (portion) where the groove 112a is provided. Further, each of the first heating element 100-1 and the second heating element 100-2 is configured to be accommodated in the groove 112a. Each of the first heating element 100-1 and the second heating element 100-2 extends in the circumferential direction within the regions A1 to A8 of the fan shapes, and is formed in a meandering manner by folding back at a circumferential end of each region.

Similar to the ceiling heater 31 described above, the first heating element 100-1 extends in the circumferential direction within the regions A1 to A8, from a center portion of the base structure 112 as a starting point at one of the end portions 104. As the first heating element 100-1 repeatedly changes its extension direction to extend between circumferential ends of each region, the first heating element 100-1 extends to about half a radius of the base structure 112 in each region, toward the center portion of the base structure 112 as an ending point at the other end of the end portions 104.

The second heating element 100-2 extends in the circumferential direction within the regions A1 to A8, from a portion of the base structure 112 outside the first heating element 100-1 as a starting point at one of end portions 104a. As the second heating element 100-2 repeatedly changes its extension direction to extend between circumferential ends of each region, the second heating element 100-2 is provided to an outer peripheral side of the base structure 112 in each region, toward the portion of the base structure 112 outside the first heating element 100-1 as an ending point at the other end of the end portions 104a such that the starting point and the ending point face each other. In such a case, the two end portions 104a are partitioned by the wall 112b, and the two end portions 104a are located at positions that are not adjacent to the folded portion 100a, and are arranged on an inner peripheral side of the second heating element 100-2.

According to the present modified example, the second temperature sensor 28 is configured to be capable of measuring both of a temperature of the first heating element 100-1 and a temperature of the second heating element 100-2. The second temperature sensor 28 is configured to be capable of independently measuring the temperature of the first heating element 100-1 and the temperature of the second heating element 100-2, and the heater driver 76-5 is configured to be capable of independently controlling the first heating element 100-1 and the second heating element 100-2.

With such a configuration, in addition to the effect of the ceiling heater 31 in the embodiments described above, it is possible to set the electric power applied to the first heating element 100-1 and the second heating element 100-2 differently. Thereby, it is possible to set a calorific value of the heating element 100-1 to be different from that of the second heating element 100-2. As a result, it is possible to set a temperature distribution of the ceiling heater 110 into a convex distribution or a concave distribution. For example, by setting an amount of the electric power applied to the second heating element 100-2 to be greater than at least the amount of the electric power applied to the first heating element 100-1, it is possible to set the temperature distribution of the ceiling heater 110 into the concave distribution.

Further, since it is possible to set the electric power applied to the first heating element 100-1 and the second heating element 100-2 differently, it is possible to set the temperature distribution of the ceiling heater 110 into the convex distribution when the temperature is elevated. Thereby, by turning on the ceiling heater 110 from a step of elevating the temperature of the substrate 18, it is possible to further improve a temperature controllability of the upper substrate, and it is also possible to improve the temperature uniformity between the substrates 18 provided at the upper portion of the boat 20. Thereby, it is possible to shorten a temperature stabilization time for the substrate 18, and it is also possible to enhance the productivity.

While the technique of the present disclosure is described in detail by way of the embodiments and the modified example described above, the technique of the present disclosure is not limited thereto. The technique of the present disclosure may be modified in various ways without departing from the scope thereof.

For example, while the embodiments and the modified example described above are described by way of an example in which one or two heating elements are used, the technique of the present disclosure is not limited thereto. For example, the technique of the present disclosure may be preferably applied when three or more heating elements are used.

For example, the embodiments and the modified example described above are described by way of an example in which the heating element 100 is configured to be curved in a meandering manner within regions divided into eight fan shapes. However, the technique of the present disclosure is not limited thereto. For example, the technique of the present disclosure may also be applied when the heating element 100 is configured to be curved in a meandering manner within regions divided into a plurality of fan shapes. For example, the technique of the present disclosure may be preferably applied when the heating element 100 is configured to be curved in a meandering manner within regions divided into eight or more fan shapes.

For example, the embodiments and the modified example described above are described by way of an example in which the SiN film is formed on the substrate 18. However, the technique of the present disclosure is not limited thereto. For example, the technique of the present disclosure may be preferably applied when forming, modifying or etching a film using the ceiling heater 31.

The technique of the present disclosure is applied to a vertical type processing apparatus capable of processing a plurality of objects to be processed at once.

According to some embodiments of the present disclosure, it is possible to suppress the deformation of the heating element.

What is claimed is:

1. A ceiling heater provided above a reaction tube, comprising:
a base structure of a disk-shape; and
a heating element continuously extending to cover a plurality of regions of the base structure, wherein a circle centered on a center of the base structure is divided into fan shapes by the plurality of regions,
wherein a portion of the heating element located in each of the plurality of regions is connected to another portion of the heating element located in an adjacent region thereof at a predetermined location, and
wherein the base structure is provided with a groove corresponding to a shape of the heating element, a wall is formed on an area of the base structure other than where the groove is located, and an interval between portions of the heating element located respectively in two adjacent regions among the plurality of regions is set to be wider than a width of the wall separating the two adjacent regions.

2. The ceiling heater of claim 1, wherein the heating element extends in a circumferential direction within each of the plurality of regions, and is curved in a meandering manner by folding back at a circumferential end of each of the plurality of regions.

3. The ceiling heater of claim 2, wherein a distance between the wall of the base structure and a side portion of each region of the heating element is set to be longer at a peripheral portion of the circle than at a central portion of the circle.

4. The ceiling heater of claim 2, wherein the heating element is rotationally symmetric.

5. The ceiling heater of claim 1, wherein the portion of the heating element located in each of the plurality of regions is connected to another portion of the heating element located in the adjacent region thereof at a peripheral portion or a central portion of the circle.

6. The ceiling heater of claim 5, wherein a distance between the wall separating the regions and a portion of the heating element closest to a circumference of the circle is set to be longer than an elongation amount due to a plastic deformation of the portion of the heating element closest to the circumference of the circle.

7. The ceiling heater of claim 5, wherein the heating element is rotationally symmetric.

8. The ceiling heater of claim 1, wherein a distance between the wall separating the regions and a portion of the heating element closest to a circumference of the circle is set to be longer than an amount of elongation due to a plastic deformation of the portion of the heating element closest to the circumference of the circle.

9. The ceiling heater of claim 1, wherein the base structure or above the heating element is open upward at least partially.

10. The ceiling heater of claim 1, further comprising:
a lid structure provided with arm structures extending radially along boundaries of the plurality of regions,
wherein a folded portion where the heating element is folded back is held between the base structure and the lid structure.

11. The ceiling heater of claim 10, wherein the base structure and the lid structure are electrically insulated.

12. The ceiling heater of claim 1, wherein the plurality of regions are obtained by dividing the circle centered on the center of the base structure into eight or more fan shapes.

13. The ceiling heater of claim 1, wherein a maximum central angle of a continuous arc portions formed by the heating element is 90° or less.

14. The ceiling heater of claim 1, wherein the base structure comprises transparent quartz.

15. The ceiling heater of claim 1, wherein the groove comprises a bottom which is roughened.

16. The ceiling heater of claim 1, wherein the base structure is configured to be capable of supporting a substantially entire bottom surface of the heating element.

17. A substrate processing method comprising:
(a) heating a substrate in a reaction tube by controlling a calorific value of a ceiling heater provided above the reaction tube; and
(b) processing the substrate by supplying a process gas to the substrate,
wherein the ceiling heater comprises:
a base structure of a disk-shape; and
a heating element continuously extending to cover a plurality of regions of the base structure, wherein a circle centered on a center of the base structure is divided into fan shapes by the plurality of regions,
wherein a portion of the heating element located in each of the plurality of regions is connected to another portion of the heating element located in an adjacent region thereof at a predetermined location, and
wherein the base structure is provided with a groove corresponding to a shape of the heating element, a wall is formed on an area of the base structure other than where the groove is located, and an interval between portions of the heating element located respectively in two adjacent regions among the plurality of regions is set to be wider than a width of the wall separating the two adjacent regions.

18. A method of manufacturing a semiconductor device comprising the method of claim 17.

19. A substrate processing apparatus comprising:
a reaction tube; and
a ceiling heater comprising:
a base structure of a disk-shape provided above the reaction tube; and
a heating element continuously extending to cover a plurality of regions of the base structure, wherein a circle centered on a center of the base structure is divided into fan shapes by the plurality of regions,
wherein a portion of the heating element located in each of the plurality of regions is connected to another portion of the heating element located in an adjacent region thereof at a predetermined location, and
wherein the base structure is provided with a groove corresponding to a shape of the heating element, a wall is formed on an area of the base structure other than where the groove is located, and an interval between portions of the heating element located respectively in two adjacent regions among the plurality of regions is set to be wider than a width of the wall separating the two adjacent regions.
